(19) United States
(12) Patent Application Publication
(10) Pub. No.: US 2013/0143407 A1
(43) Pub. Date: Jun. 6, 2013

(54) METHOD FOR PRODUCING A THIN SINGLE CRYSTAL SILICON HAVING LARGE SURFACE AREA

(71) Applicants: CHING-FUH LIN, Taipei (TW); TZU-CHING LIN, Taipei (TW); SHU-JIA SYU, Taipei (TW)

(72) Inventors: CHING-FUH LIN, Taipei (TW); TZU-CHING LIN, Taipei (TW); SHU-JIA SYU, Taipei (TW)

(73) Assignee: NATIONAL TAIWAN UNIVERSITY, Taipei (TW)

(21) Appl. No.: 13/414,355

(22) Filed: Mar. 7, 2012

(30) Foreign Application Priority Data
Dec. 6, 2011 (TW) 100144941

(51) Int. Cl. H01L 21/311; B82Y 40/00

(52) U.S. Cl. 438/694; 977/888; 257/E21.249

(57) ABSTRACT

The present invention relates to a method for producing a thin single crystal silicon having large surface area, and particularly relates to a method for producing a silicon micro and nanostructure on a silicon substrate (or wafer) and lifting off the silicon micro and nanostructure from the silicon substrate (or wafer) by metal-assisted etching. In this method, a thin single crystal silicon is produced in the simple processes of lifting off and transferring the silicon micro and nanostructure from the substrate by steps of depositing metal catalyst on the silicon wafer, vertically etching the substrate, laterally etching the substrate. And then, the surface of the substrate is processed, for example planarizing the surface of the substrate, to recycle the substrate for repeatedly producing thin single crystal silicons. Therefore, the substrate can be fully utilized, the purpose of decreasing the cost can be achieved and the application can be increased.

### CROSS-REFERENCE TO RELATED APPLICATIONS

The entire contents of Taiwan Patent Application No. 100144941, filed on Dec. 6, 2011, from which this application claims priority, are incorporated herein by reference.

### BACKGROUND OF THE INVENTION

1. Field of the Invention

The present invention relates to a method for producing a thin single crystal silicon having large surface area, and particularly relates to a method for producing a silicon micro and nanostructure on a silicon substrate (or wafer) and lifting off the silicon micro and nanostructure from the silicon substrate (or wafer) by metal-assisted etching.

2. Description of Related Art

Currently, thin single crystal silicon, for example silicon microstructure and silicon nanostructure (or called silicon micro and nanostructure for short), is applied in many fields. For example, waveguides or lasers of photoelectric field, antireflection layers or PN junctions of solar cell, and electronic components (such as transistor) of semiconductor process adopt silicon micro and nanostructures. Most of these silicon micro and nanostructures are formed on silicon wafers (or silicon substrates). There are many methods to form the silicon micro and nanostructures on silicon wafers (or silicon substrates). Generally, their methods can be classified into two different methods: bottom-up method and top-down method. In the bottom-up method, vapor-liquid-solid (VLS), chemical vapor deposition (CVD), thermal evaporation, or solution method, which has a need of high vacuum, high temperature, or high pressure to form the silicon micro and nanostructures and has a need of expensive devices to form the silicon micro and nanostructures, is adopted for producing the silicon micro and nanostructures.

The top-down method comprises dry etching and wet etching. The dry etching also needs to be performed in high vacuum and it also needs an expensive device. Comparing with above-mentioned methods, wet etching or so-called chemical etching has an advantage of low cost, for example dipping silicon in a potassium hydroxide (KOH) solution or the metal-assisted etching in which the silicon is dipped in an aqueous solution of hydrofluoric acid (HF)/silver nitride (AgNO₃). However, whether above-mentioned expensive method for producing the silicon micro and nanostructures or the wet etching having an advantage of low cost is applied, most of silicon micro and nanostructures having good quality of crystal lattice need to be formed on a silicon substrate. If the silicon micro and nanostructures can be produced on a silicon substrate, these silicon micro and nanostructures can be transferred to another substrate or lifted off to form an independent thin film silicon and the remained substrate can be recycled to produce the silicon micro and nanostructures repeatedly, it will significantly decrease the waste of materials and increase the applications of the silicon micro and nanostructures. Now, for transferring the micro and nanostructures or the micro and nano thin film structures, the multi-layered structure, for example multi-layered epitaxial layer made of III-V semiconductor materials, is necessary. One layer of the multi-layered structure is an etching sacrificial layer. Only this etching sacrificial layer is removed by selective etching, the structure on this etching sacrificial layer can be transferred from the original substrate. Or, a silicon on insulator (SOI) wafer is applied to produce silicon microstructures, silicon nanostructures or thin film semiconductor material, and the silicon dioxide layer in intermediate position of the SOI wafer (or substrate) is etched. Therefore, the silicon structure on the silicon dioxide layer can be moved apart from the original substrate (or wafer).

### SUMMARY OF THE INVENTION

In view of the foregoing, one object of the present invention is to provide a method for producing a thin single crystal silicon having large surface area. In this method, the microstructure or nanostructure can be formed on a substrate by simple steps, and the microstructure or nanostructure can be transferred to another substrate or lifted off to form an independent thin film silicon. Therefore, the substrate can be recycled and utilized repeatedly, so the waste of silicon substrate and the production cost of the silicon microstructure or nanostructure can be decreased.

According to the objects above, a method for producing a thin single crystal silicon having large surface area is disclosed herein. The method comprises following steps: 1) providing a substrate made of a single material; (2) forming a designed and patterned metal barrier layer on the substrate to define an etching area on the substrate; (3) depositing or attaching a metal catalyst on the substrate; (4) dipping the substrate into a first etching solution to vertically etching the substrate to form a microstructure or a nanostructure; (5) dipping the substrate into a second etching solution to laterally etching the bottom of the microstructure or said nanostructure to lift off the microstructure or the nanostructure from the substrate; (6) transferring the microstructure or the nanostructure from the substrate; (7) processing the surface of the substrate for forming another microstructure or nanostructure on the substrate; and performing step (1)-step (7) to form a microstructure or a nanostructure on said substrate repeatedly.

Pre-forming a patterned mask (or metal barrier layer) on the substrate, this step can design different patterns according to requirements of applications. This means that the patterned mask (or metal barrier layer) can be designed to have various patterns in this step according to requirements of applications. And, this step can control the surface area to reduce number of surface energy levels and it helps decrease the recombination probability of carriers on the surface. Therefore, the method of this invention can be applied to solar cells. In addition, because the pattern of the mask (or metal barrier layer) can be designed in different forms or to have different shapes, electronic components and circuits can be formed on the substrate, and then, a thin integrated circuit (IC) is formed after the electronic components and circuits are lifted off from the substrate. Because this material utilized to form the electronic components is a single crystal material and it has high carrier mobility, the electronic components made of this material respond much faster than those made of amorphous silicon material or poly silicon material. This thin film silicon (or single crystal material) can be placed on various kinds of substrate materials, and it can be put on a non-planar object because it is flexible. Therefore, the applications of the thin film silicon are increased.

This invention adopts a substrate made of a single material. This invention not only utilizes a simpler method to produce a silicon microstructure or silicon nanostructure on the substrate, but also separates the silicon microstructure or silicon nanostructure from the substrate and transfers the silicon microstructure or silicon nanostructure from the substrate. Presently, only a multi-layered structure, for example a multi-layered epitaxial layer made of III-V semiconductor materials, has the ability to transfer the silicon microstructure, silicon nanostructure or thin film semiconductor material from the substrate and to recycle the substrate. One layer of the multi-layered structure is an etching sacrificial layer. Only this etching sacrificial layer is removed by selective etching, the structure on this etching sacrificial layer can be transferred from the original substrate. Or, a silicon on insulator (SOI) wafer is applied to produce silicon microstructures, silicon nanostructures or thin film semiconductor materials. After the silicon dioxide layer in intermediate position of the SOI wafer (or substrate) is etched, the silicon structure on the silicon dioxide layer can be moved apart from the original substrate (or wafer). However, this invention can separate and transfer silicon microstructures or silicon nanostructures from the original substrate without this multi-layered structure. This multi-layered structure is necessary for this invention. The recycled substrate can be utilized to produce the thin film silicon again or utilized to produce the thin film silicon repeatedly by the method of this invention. Therefore, the producing process of silicon microstructures or silicon nanostructures can be simplified and the cost of the producing process can be reduced.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1F are a series of cross-section drawings illustrating a method for producing a thin single crystal silicon having large surface area in accordance with an embodiment of the present invention.

FIG. 2A to FIG. 2G are a series of cross-section drawings illustrating a method for producing a thin single crystal silicon having large surface area in accordance with another embodiment of the present invention.

FIG. 3A to FIG. 3H are drawings illustrating various kinds of patterns of metal barrier layers (or masks) in accordance with different embodiments of the present invention.

FIG. 4A to FIG. 4C are a SEM image in plane view of a thin single crystal silicon, a SEM image in cross-section view of a thin single crystal silicon, and a SEM image in cross-section view of laterally etching on sidewalls of microholes respectively in accordance with one embodiment of the present invention.

FIG. 5A to FIG. 5D are a SEM image in plane view of a thin single crystal silicon, a SEM image in cross-section view of a thin single crystal silicon, a SEM image in cross-section view of the sidewalls of the microstructure (or nanostructure) with metal particles attached thereon, and an enlarged SEM image in cross-section view of the bottom of the microstructure (or nanostructure) respectively in accordance with one embodiment of the present invention.

### DETAILED DESCRIPTION OF THE PREFERRED EMBODIMENT

The detailed description of the present invention will be discussed in the following embodiments, which are not intended to limit the scope of the present invention, and can be adapted for other applications. While drawings are illustrated in detail, it is appreciated that the quantity of the disclosed components may be greater or less than that disclosed, except where expressly restricting the amount of the components. Although specific embodiments have been illustrated and described, it will be appreciated by those skilled in the art that various modifications may be made without departing from the scope of the present invention, which is intended to be limited solely by the appended claims.

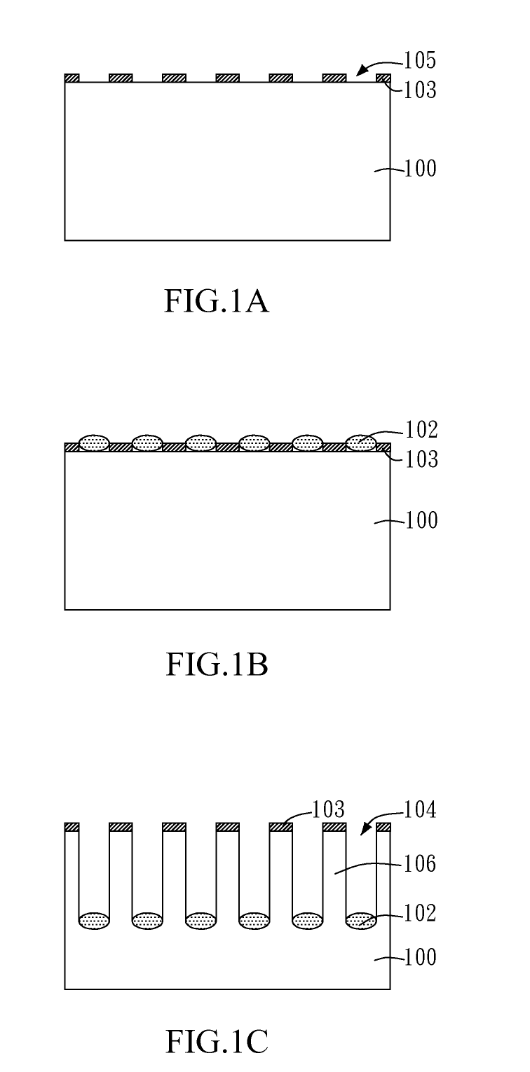

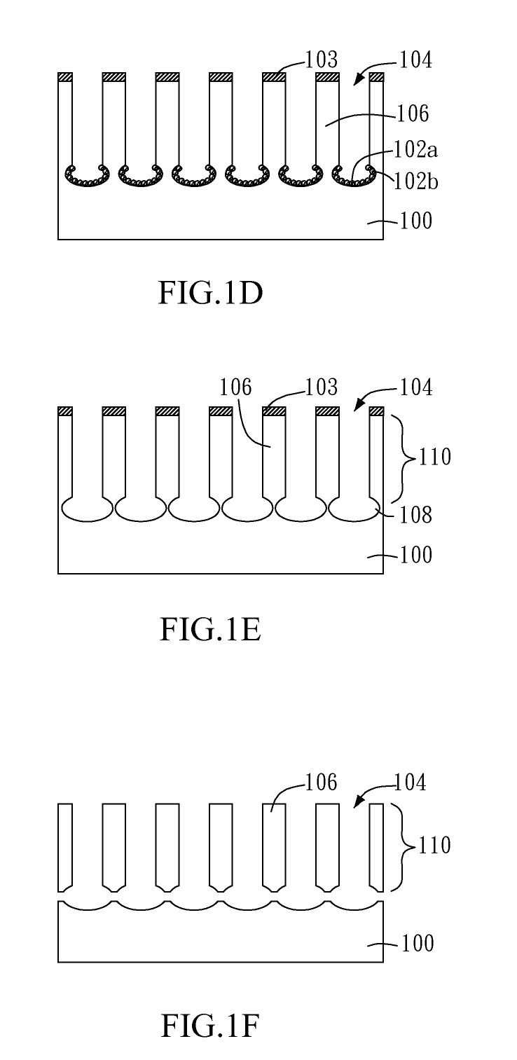

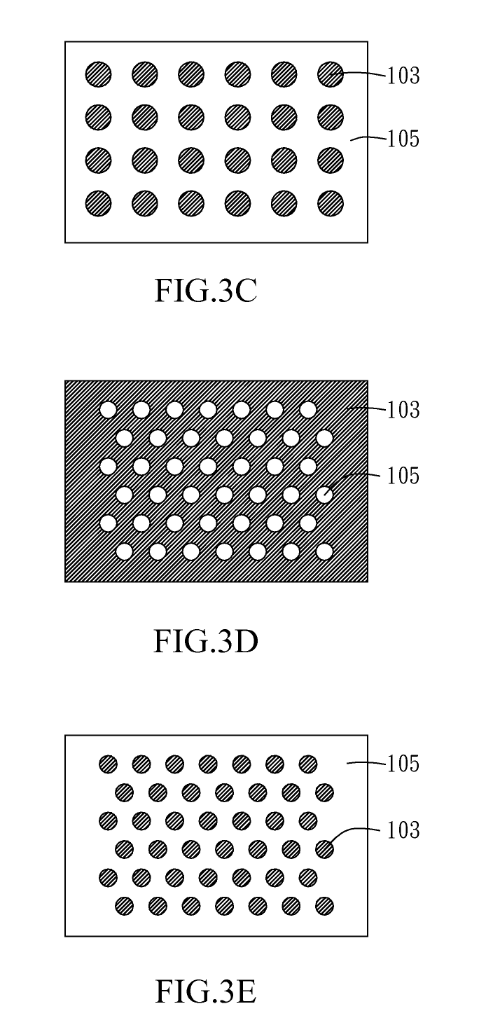

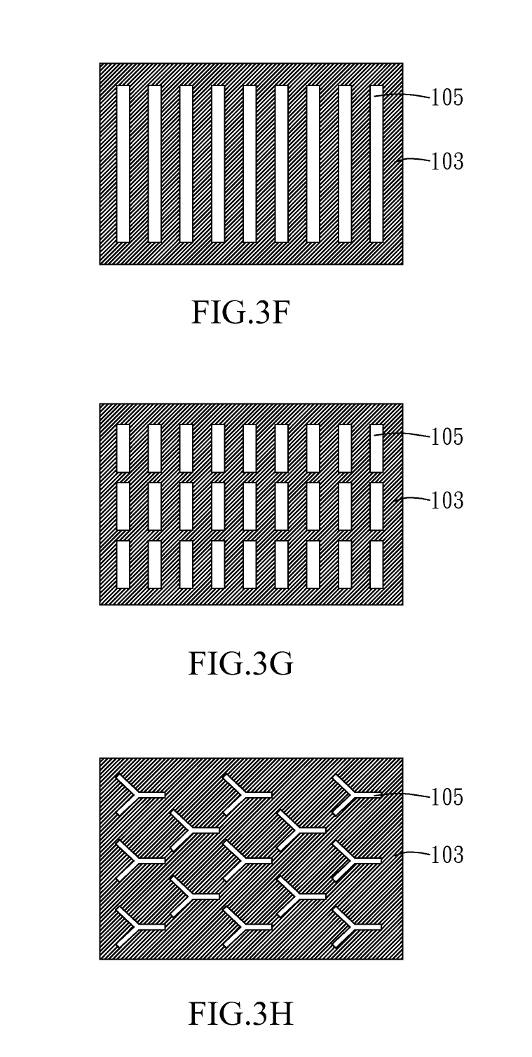

FIG. 1A to FIG. 1F are a series of cross-section drawings illustrating a method for producing a thin single crystal silicon having large surface area in accordance with an embodiment of the present invention. Referring to FIG. 1A, first, a substrate 100 made of a single material is provided and a patterned mask or so-called metal barrier layer 103 is defined on the substrate 100. The metal barrier layer 103 is used to prevent metal from contacting the silicon of the substrate 100. The substrate 100 is a silicon wafer or a silicon substrate. Different etching areas 105 can be defined by covering of different metal barrier layers 103 having different patterns or by different patterns composed of metal barrier layer 103, and what kind of microstructure or nanostructure is produced can be determined by the pattern of the metal barrier layer 103 or by the pattern composed of the metal barrier layer 103. This will be described in detail. These patterns can be a crisscrossed pattern, a dotted pattern, a bar pattern, or a Y-shaped pattern illustrated in FIG. 3A-FIG. 3H. The patterns illustrated in FIG. 3A-FIG. 3H are only used as examples for describing but not used to be limits. According to requirements and concerns of the production process, the patterns can be changed and modified or different patterns, such as a square pattern, a hexagon pattern, or a parallelogram pattern, or the pattern is formed as a network pattern or a straight line pattern. Therefore, this invention does not give any limit for the pattern of the metal barrier layer (or mask) 103. In FIG. 3A-FIG. 3H, the slash portion (the portion labeled as 103) represents the metal barrier layer, and the blank portion (the portion labeled as 105) represents the hollow portions of the metal barrier layer (i.e., the pattern of the metal barrier layer or the position which metal catalyst is deposited on). The metal barrier layer 103 is a photoresist, organic polymer, silicon oxide (SiₓO_{y}), or silicon nitride (SiₓN_{y}), and the patterned metal barrier layer 103 covers the substrate 100 or is formed on the substrate 100 to define said etching area 105 on the substrate 100 by photo lithography, electron-beam lithography, microsphere array or nanosphere array, imprint lithography, or other method capable of defining the pattern of the microstructure or nanostructure.

Referring to FIG. 1B, after the surface of the substrate 100 exposed from the hollow portions of the metal barrier layer 103 is defined as etching areas 105, a metal catalyst 102 is deposited on or attached to the etching areas 105 of the substrate 100 by electroless metal deposition (EMD), sputter, e-beam evaporation, or thermal evaporation to contact the substrate 100. The metal catalyst 102 is gold (Au), silver (Ag), platinum (Pt), copper (Cu), iron (Fe), manganese (Mn), or cobalt (Co), but not limited to this. Other metals capable of being used as redox mediators can be used as the metal catalyst 102 according to requirements of production process. If the electroless metal deposition (EMD) is adopted to deposit the metal catalyst 102 on the substrate 100, an aqueous solution of hydrofluoric acid (HF)/potassiumchloroaurate (KAuCl₄), an aqueous solution of hydrofluoric acid (HF)/silver nitride (AgNO₃), an aqueous solution of hydrofluoric acid (HF)/potassium hexachloroplatinate (K₂PtCl₄), an aqueous solution of hydrofluoric acid (HF)/copper nitride (Cu(NO₃)₂), an aqueous solution of hydrofluoric acid (HF)/ferric nitride (Fe(NO₃)₃), an aqueous solution of hydrofluoric acid (HF)/manganous nitride (Mn(NO₃)₃), an aqueous solution of hydrofluoric acid (HF)/cobaltous nitride (Co(NO₃)₃), or a mixed solution in which other salts and other reducing agents are mixed can be used as chemical solution of the electroless metal deposition (EMD). Of course, the electroless metal deposition can adopt different concentration of this chemical solution according to requirements and concerns of production process. Therefore, this invention does not give any limit about the concentration of the chemical solution.

And then, referring to FIG. 1C, the substrate 100 is dipped in a first etching solution to vertically etch the substrate 100 for producing a silicon microstructure or a silicon nanostructure after the metal catalyst 102 is deposited on (or attached to) the substrate 100 having patterned metal barrier layer 103 deposited thereon. The first etching solution is composed of a chemical solution capable of etching oxide and a chemical solution capable of oxidizing silicon, for example an aqueous solution of hydrofluoric acid (HF)/hydrogen peroxide (H₂O₂) or a mixed aqueous solution capable of oxidizing silicon and etching silicon oxide simultaneously. The molar ratio of the chemical solution capable of etching oxide/the chemical solution capable of oxidizing silicon in the first etching solution, for example the molar ratio of hydrofluoric acid (HF)/hydrogen peroxide (H₂O₂) is greater than 35/1, but not limited to this. The molar ratio of the chemical solution capable of etching oxide/the chemical solution capable of oxidizing silicon in the first etching solution can be changed or modified according to requirements and concerns of production process. The temperature of the first etching solution is in the range of 10° C.-100° C. The hydrogen peroxide (H₂O₂) in the first etching solution oxidizes the surface of the substrate 100 which contacts the metal catalyst 102 (i.e., the surface of the substrate 100 under the metal catalyst 102) to form silicon oxide by the metal catalyst 102. And then, the hydrofluoric acid (HF) in the first etching solution etches the silicon oxide on the substrate 100. When the silicon oxide is completely etched, the metal catalyst 102 follows down to contact the newly exposed surface of the substrate 100 and foregoing reactions (or steps) are repeated to etch the newly exposed surface of the substrate 100. The surface of the substrate 100 contacting the bottom of the metal catalyst 102 is etched continuously by repeating foregoing reactions (or steps) because only the bottom of the metal catalyst 102 contacts the surface of the substrate 100. Therefore a vertical etching is created on substrate 100.

The substrate 100 is vertically etched to a predetermined depth though above-mentioned reactions (or steps). Therefore, the desired silicon microstructure or silicon nanostructure is formed and the desired thickness of the desired silicon microstructure or silicon nanostructure is created by the vertical etching. The depth of vertical etching is selected and determined according to the kind and the thickness of the silicon microstructure or the silicon nanostructure. Therefore, this invention does not give any limit about the depth of vertical etching.

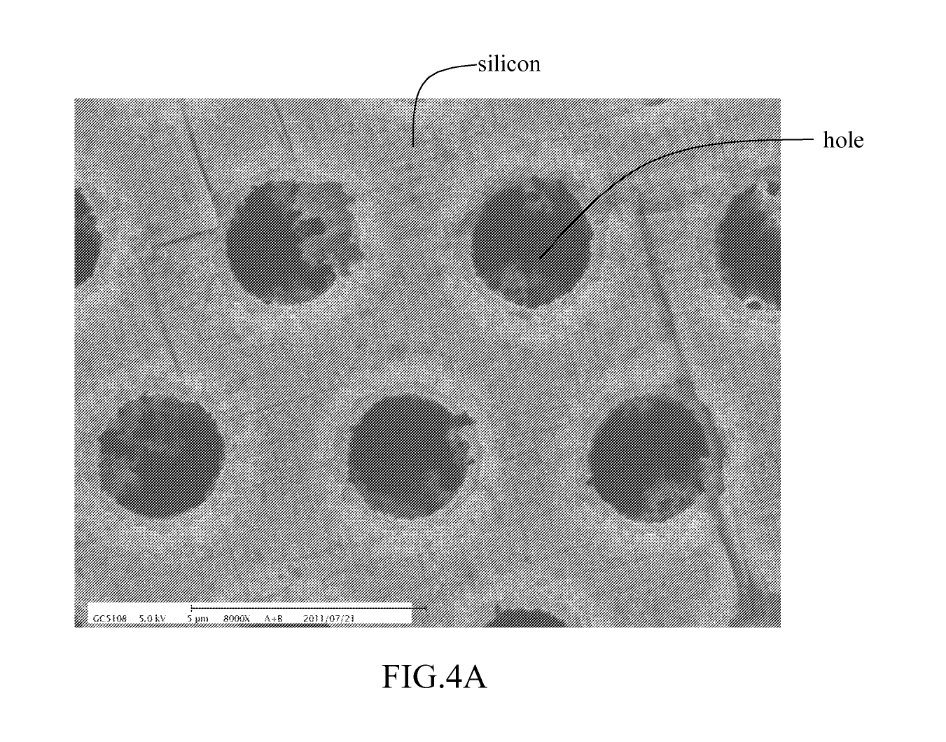

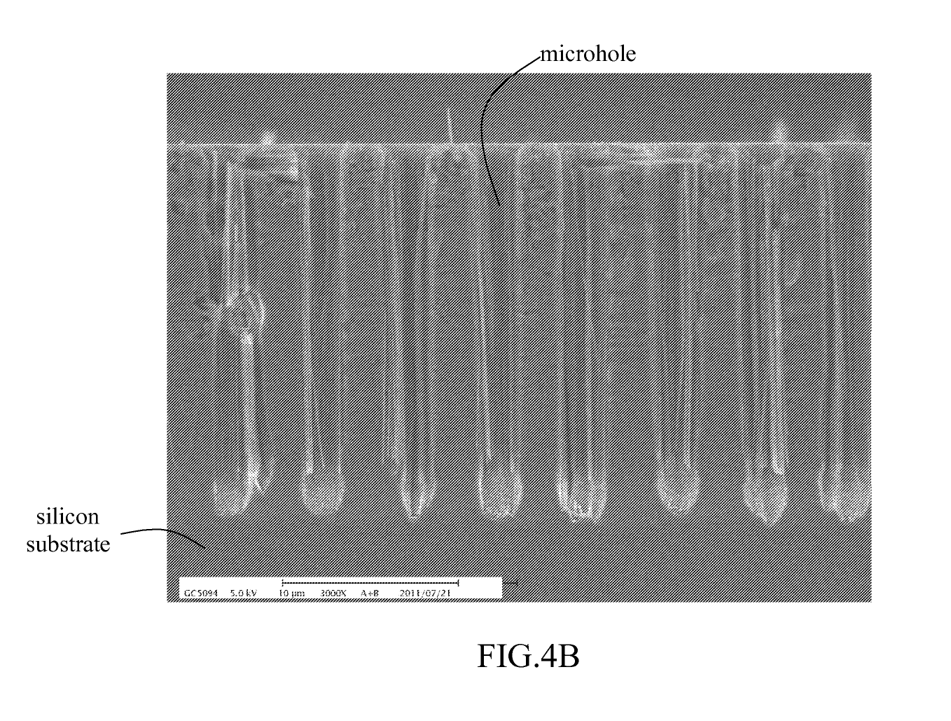

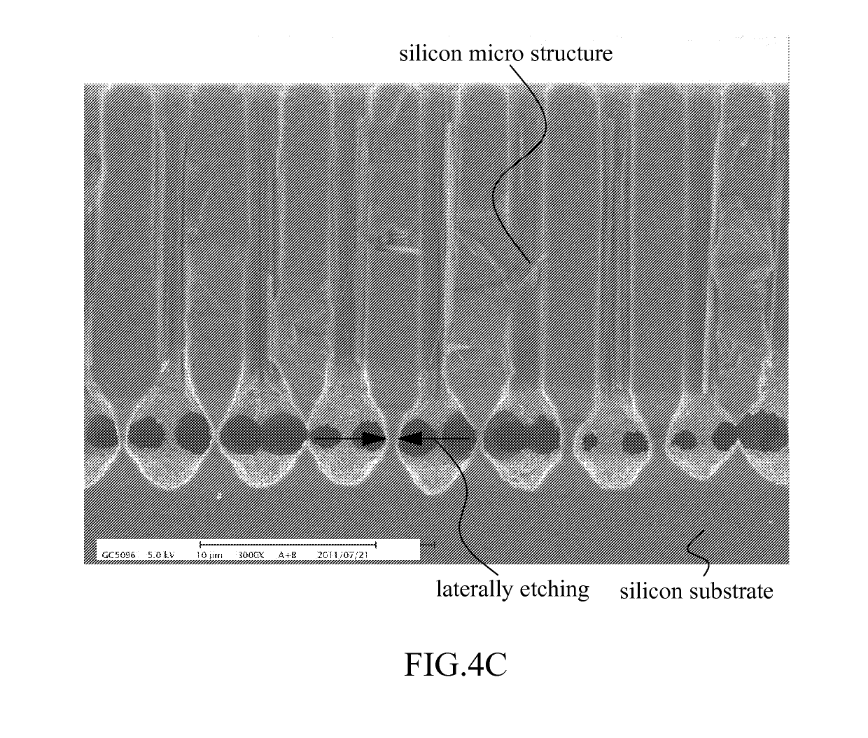

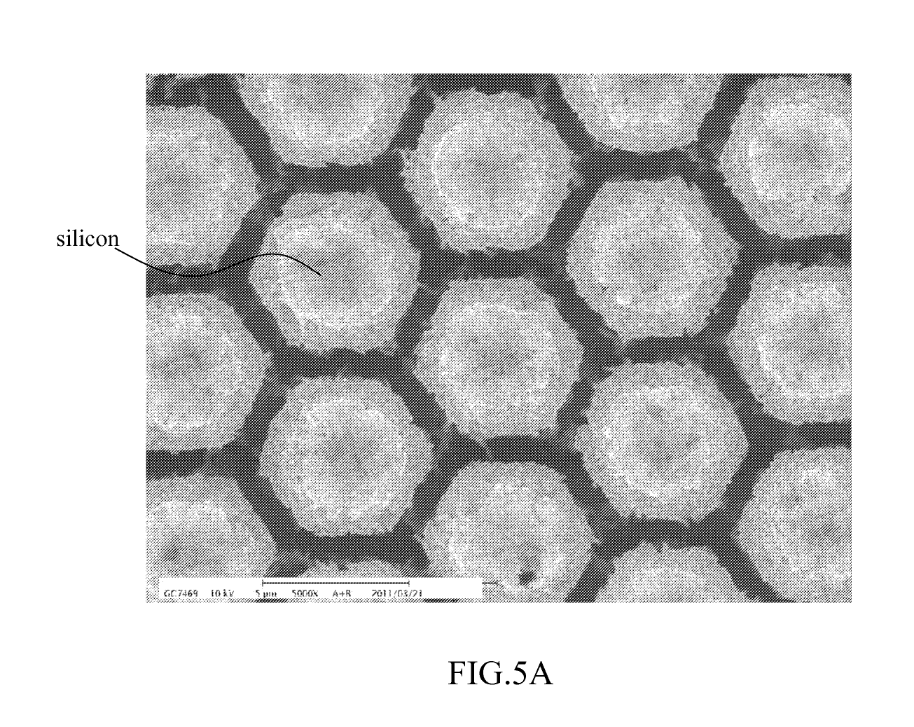

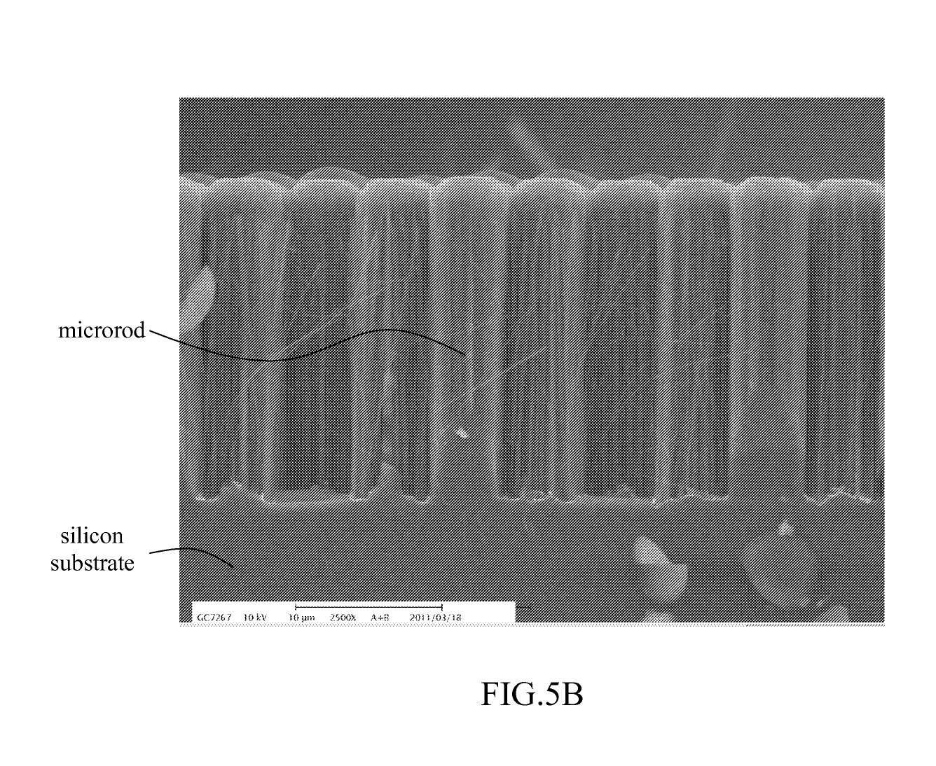

Different etching areas 105 are defined on the substrate 100 through covering of different patterned metal barrier layers 103 or different patterns composed of the metal barrier layers 103, and they further determine the kind of the silicon microstructure or the silicon nanostructure. After the vertical etching, only the surface of the substrate 100 which is not covered by the metal barrier layer 103 (i.e., the surface corresponded to the pattern of the metal barrier layer 103) is etched. If the metal barrier layer 103 has a hole-like pattern (as FIG. 3B and FIG. 3D show), many holes 104, which do not connect with each other, are formed on the substrate 100 to form the silicon microstructure or the silicon nanostructure after the vertical etching. At this time, the holes labeled as 104 in FIG. 1C are the silicon microholes and the silicon nanoholes, and the structures labeled as 106 in FIG. 1C are the non-etched areas on the substrate 100. Referring to actual experiment result, as FIG. 4A and FIG. 4B show, a hole-like structure is formed on the silicon substrate through the vertical etching. FIG. 4A is a scanning electron microscope (SEM) image in plane view of the hole-like structure, and FIG. 4B is a SEM image in cross-section view of the hole-like structure.

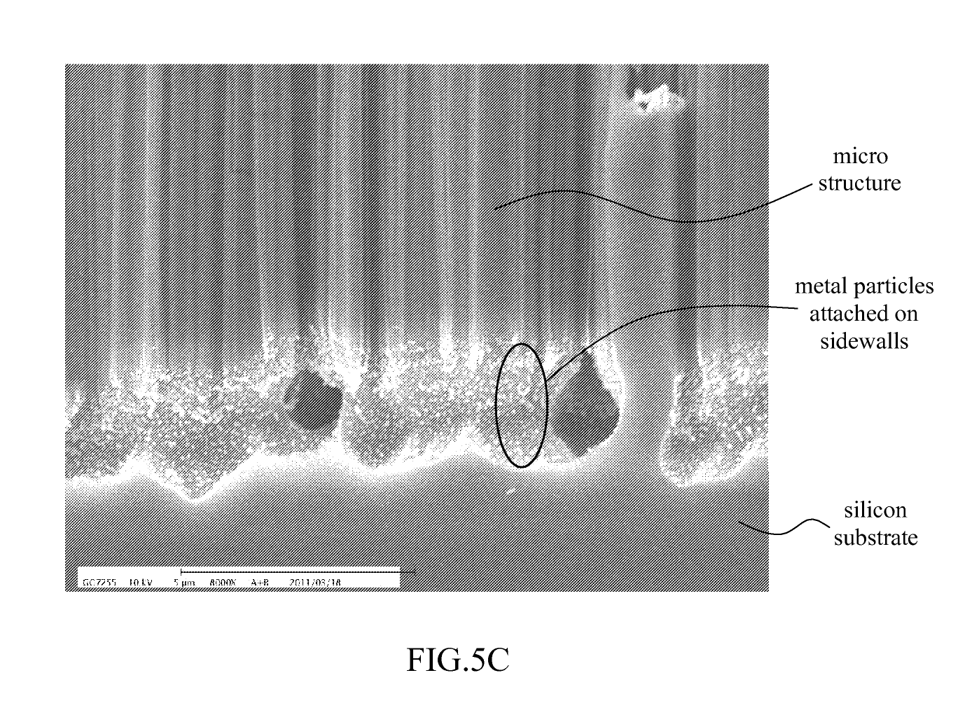

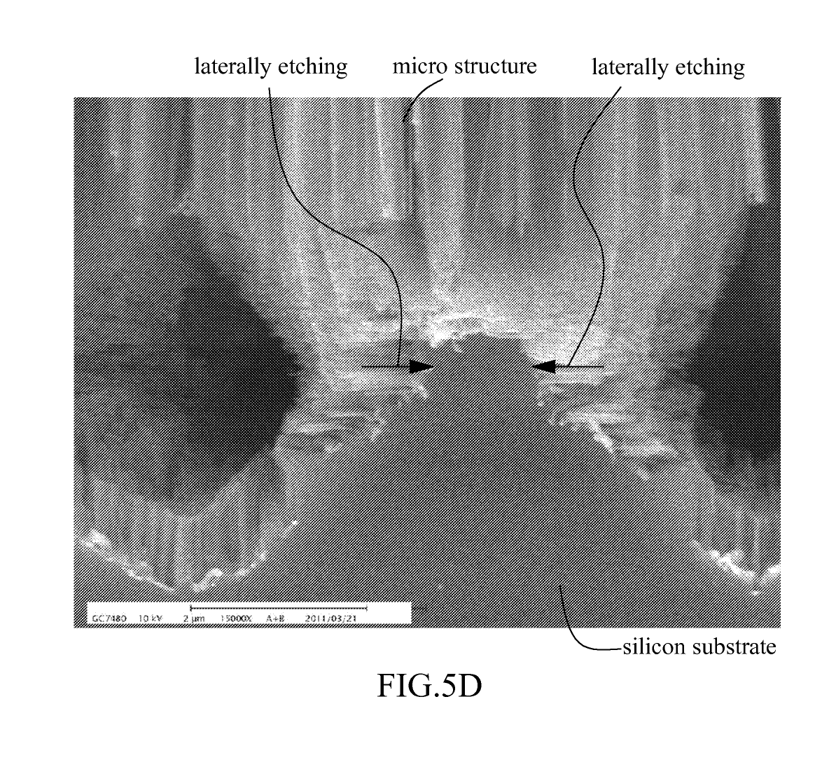

Another embodiment of determining the kind of the microstructure or the nanostructure by the metal barrier layer 103 is disclosed herein. After the metal barrier layer 103 is formed on the substrate 100 or the metal barrier layer 103 creates the designated pattern on the substrate 100 wherein the metal barrier layer 103 has a pattern composed of discontinuous arranges of hexagons, the most surface of the substrate 100 are exposed to be defined as etching areas 105 and the metal catalyst 102 is deposited on or attached to the etching areas 105. After the vertical etching, most portions of the substrate 100 are etched and only the portions of the substrate which are covered by the metal barrier layer 103 are etched. Therefore, many line-like structures or rod-like structures are formed on the substrate 100 to form the silicon microwire structure or the silicon nanowire structure, or the silicon microrod structure or the silicon nanorod structure. At this time, the holes labeled as 104 in FIG. 1C are the etched holes, and the structures labeled as 106 in FIG. 1C are the silicon microwire structures or the silicon nanowire structures, or the silicon microrod structures or the silicon nanorod structures on the substrate 100. Referring to actual experiment result, as FIG. 5A and FIG. 5B show, a rod-like structure is formed on the silicon substrate through the vertical etching. FIG. 5A is a SEM image in plane view of the rod-like structure, and FIG. 5B is a SEM image in cross-section view of the rod-like structure. Of course, according to the requirements and designs of the production process and products, various metal barrier layers having different patterns can be adopted to cover the substrate or different patterns can be constituted by the metal barrier layer to produce different kinds of the silicon microstructure or the silicon nanostructure, for example the silicon microwire structure or the silicon nanowire structure, the silicon microhole structure or the silicon nanohole structure, the silicon microrod structure or the silicon nanorod structure, the bar-like silicon microstructure or the bar-like silicon nanostructure, or the network-like silicon microstructure or the network-like silicon nanostructure, but not limited to this.

Referring to FIG. 1D, after the vertical etching, the substrate 100 is dipped in a second etching solution to laterally etch the bottom of the microstructure or the nanostructure for separating the microstructure or the nanostructure from the substrate 100 or for weakening the connection between the substrate 100 and the bottom of the microstructure or the nanostructure. Therefore, it is easy to move the microstructure or the nanostructure apart from the substrate 100. The second etching solution is composed of a chemical solution capable of etching oxide and a chemical solution capable of oxidizing silicon, for example an aqueous solution of hydrofluoric acid (HF)/hydrogen peroxide (H₂O₂) or a mixed aqueous solution capable of oxidizing silicon and etching silicon oxide simultaneously. The molar ratio of the chemical solution capable of etching oxide/the chemical solution capable of oxidizing silicon in the second etching solution, for example the molar ratio of hydrofluoric acid (HF)/hydrogen peroxide (H₂O₂) is smaller than 35/1, but not limited to this. The molar ratio of the chemical solution capable of etching oxide/the chemical solution capable of oxidizing silicon in the second etching solution, for example the molar ratio of hydrofluoric acid (HF)/hydrogen peroxide (H₂O₂), can be changed or modified according to requirements and concerns of production process. However, the molar ratio of the chemical solution capable of etching oxide/the chemical solution capable of oxidizing silicon in the second etching solution, for example the molar ratio of hydrofluoric acid (HF)/hydrogen peroxide (H₂O₂), must be smaller than the molar ratio of the chemical solution capable of etching oxide/the chemical solution capable of oxidizing silicon in the first etching solution. The temperature of the second etching solution is in the range of 10° C.-100° C.

In this step, the molar ratio of the chemical solution capable of etching oxide/the chemical solution capable of oxidizing silicon, for example the molar ratio of hydrofluoric acid (HF)/hydrogen peroxide (H₂O₂), is reduced and this means that the chemical solution capable of oxidizing silicon, for example hydrogen peroxide (H₂O₂), is increased. Therefore, when the hydrogen peroxide (H₂O₂) oxidizes the surface of the substrate 100 which contacts the bottom of the metal catalyst 102, the hydrogen peroxide (H₂O₂) also oxidizes the metal catalyst 102 to form metal ions and the metal ions are distributed on the sidewalls of the etched holes 104. Therefore, the metal catalyst 102a and 102b are distributed on the bottoms and the sidewalls of the etched holes 104 respectively, as FIG. 1D shows. By this way, the metal catalysts 102a, 102b catalyze the hydrogen peroxide (H₂O₂) to oxidize the bottoms and the sidewalls of the etched holes 104 simultaneously for forming silicon oxide on both of the bottoms and the sidewalls. Therefore, the chemical solution capable of etching oxide, for example hydrofluoric acid (HF), etches both of the bottoms and the sidewalls of the etched holes 104 simultaneously, and a lateral etching is created to perform a laterally etching 108 for etching the sidewalls of the etched holes 104.

Referring to FIG. 1E, after the sidewalls of the etched holes 104 are laterally etched for a while, for example several minutes to several hours, it is determined according to the requirements of production process and products, the bottoms of the etched holes 104 are close to each other or the bottoms of the etched holes 104 are connected with each other by the laterally etching 108. Therefore, the silicon microstructure or the silicon nanostructure on the substrate 100 becomes a silicon microstructure thin film or a silicon nanostructure thin film 110 through the laterally etching 108, and the connections between the substrate 100 and the bottom of the silicon microstructure thin film or the silicon nanostructure thin film 110 are weakened or completely removed by the laterally etching 108. Referring to actual experiment result, as FIG. 4C shows, the lateral etching weakens the connection between the bottoms of the microholes and the silicon substrate. According to the requirements and designs of the production process, the silicon microstructure thin film or the silicon nanostructure thin film 110 can be produced as various kinds of the silicon microstructure thin film or the silicon nanostructure thin film, for example the silicon microwire thin film or the silicon nanowire thin film, the silicon microhole thin film or the silicon nanohole thin film, the silicon microrod thin film or the silicon nanorod thin film, the bar-like silicon microstructure thin film or the bar-like silicon nanostructure thin film, or the network-like silicon microstructure thin film or the network-like silicon nanostructure thin film, but not limited to this. Therefore, it is easy to separate or lift off the silicon microstructure thin film or the silicon nanostructure thin film 110 from the substrate 100. The time dipped the substrate 100 in the second etching solution and the concentration of the second etching solution is determined according to the requirements and designs of the production process and products, and they can be changed and modified according to the requirements and designs of the production process and products. Therefore, this invention does not give any limit about the dipped time and the concentration of the second etching solution. The only limit is that the molar ratio of the chemical solution capable of etching oxide/the chemical solution capable of oxidizing silicon in the second etching solution must be smaller than the molar ratio of the chemical solution capable of etching oxide/the chemical solution capable of oxidizing silicon in the first etching solution. The thickness of the silicon microstructure thin film or the silicon nanostructure thin film 110 formed by the lateral etching is in range of 50 nm²-10 μm². The silicon microstructure thin film or the silicon nanostructure thin film 110 is the silicon microwire thin film or the silicon nanowire thin film, the silicon microhole thin film or the silicon nanohole thin film, the silicon microrod thin film or the silicon nanorod thin film, or other kinds of the silicon microstructure thin film or the silicon nanostructure thin film.

Referring to FIG. 1F, after the lateral etching, if there is not any connection between the substrate 100 and the silicon microstructure thin film or the silicon nanostructure thin film 110, the silicon microstructure thin film or the silicon nanostructure thin film 110 can be taken from the substrate 100 directly. If there are still some connections between the substrate 100 and the silicon microstructure thin film or the silicon nanostructure thin film 110, the silicon microstructure thin film or the silicon nanostructure thin film 110 is lifted off and transferred from the substrate 100. In this step, the silicon microstructure thin film or the silicon nanostructure thin film 110 is lifted off from the substrate 100 directly or the silicon microstructure thin film or the silicon nanostructure thin film 110 is lifted off from the substrate 100 after remained connections between the substrate 100 and the silicon microstructure thin film or the silicon nanostructure thin film 110 are completely broken by ultrasonic wave, because the connections between the bottom of the silicon microstructure thin film (or the silicon nanostructure thin film) 110 and the substrate 100 are weakened or completely removed by the previous lateral etching. Generally, this method (or technique) is adopted to lift off and transfer the silicon microstructure thin film (or the silicon nanostructure thin film) 110 when the silicon microstructure or the silicon nanostructure is silicon microhole or the silicon nanohole. In another embodiment of this invention, scraping the silicon microstructure thin film or the silicon nanostructure thin film is scraped from the substrate to form powders of the silicon microstructure or the silicon nanostructure or to form a sheet-like silicon microstructure or sheet-like silicon nanostructure. The area of the sheet-like silicon microstructure or sheet-like silicon nanostructure is in the range of 50 nm²-10 μm². Or, in another embodiment of this invention, the microstructure or the nanostructure is lifted off from the substrate and transferred to a carrier substrate by transfer printing, sticking, or material stress. In this method, the microstructure (thin film) or the nanostructure (thin film) is adhered on or attached to the carrier substrate by an adhesive material, and then, both of the carrier substrate and the microstructure (thin film) or the nanostructure (thin film) are lifted off from the substrate 100. They can be lifted off from the substrate 100 directly, or they can be lifted off from the substrate 100 after remained connections between the substrate 100 and the silicon microstructure (thin film) or the silicon nanostructure (thin film) are completely broken by ultrasonic wave. The carrier substrate comprises silicon, III-V semiconductor, glass, transparent conductive glass, plastic substrate, metal plate or foil, or other materials suitable for applying to silicon microstructures or silicon nanostructures. The adhesive material is a polymer, conductive organic material, metal adhesive, electron and hole transport material, or photon transport material.

After the silicon microstructure thin film or the silicon nanostructure thin film 110 is lifted off or transferred from the substrate 100, the surface of the substrate 100 is processed to planarize the surface by metal assisted etching, chemical polishing, mechanical polishing, or other methods capable of planarizing the surface of the substrate 100. By this step, the substrate 100 can be recycled to produce another silicon microstructure or another silicon nanostructure thereon. And then, the steps shown in FIG. 1A-FIG. 1F are repeated to produce microstructures or nanostructures on the substrate 100 repeatedly and to recycle the substrate 100 repeatedly until the thickness, the hardness or other qualities of the substrate 100 cannot meet the requirements and conditions of the production process any further.

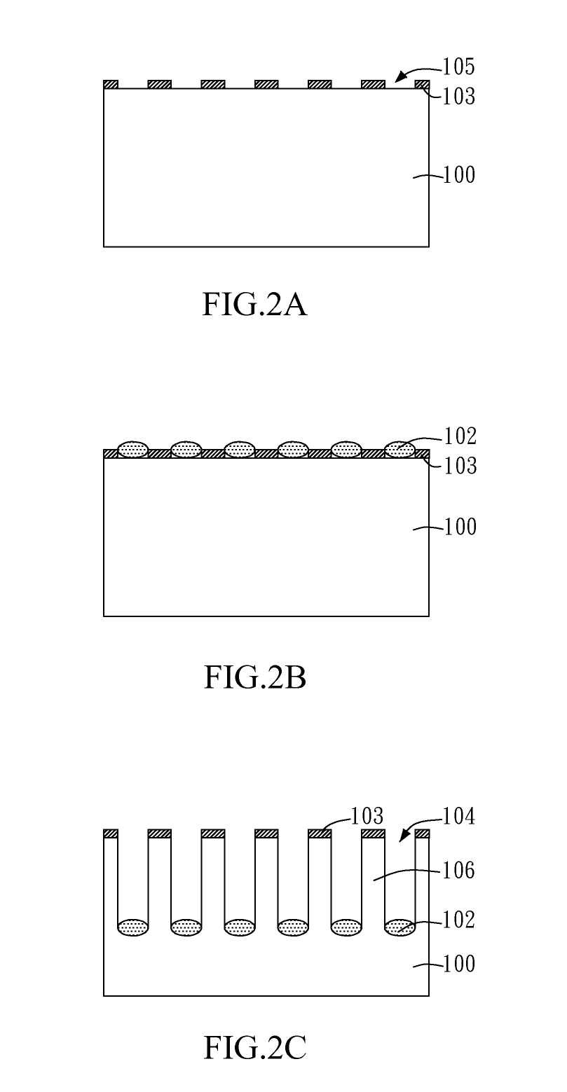

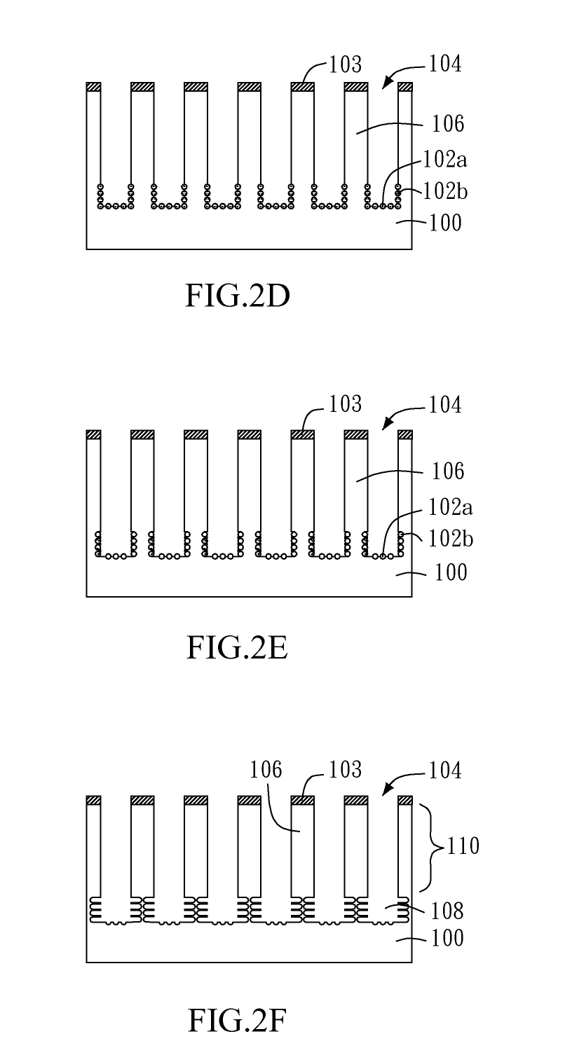

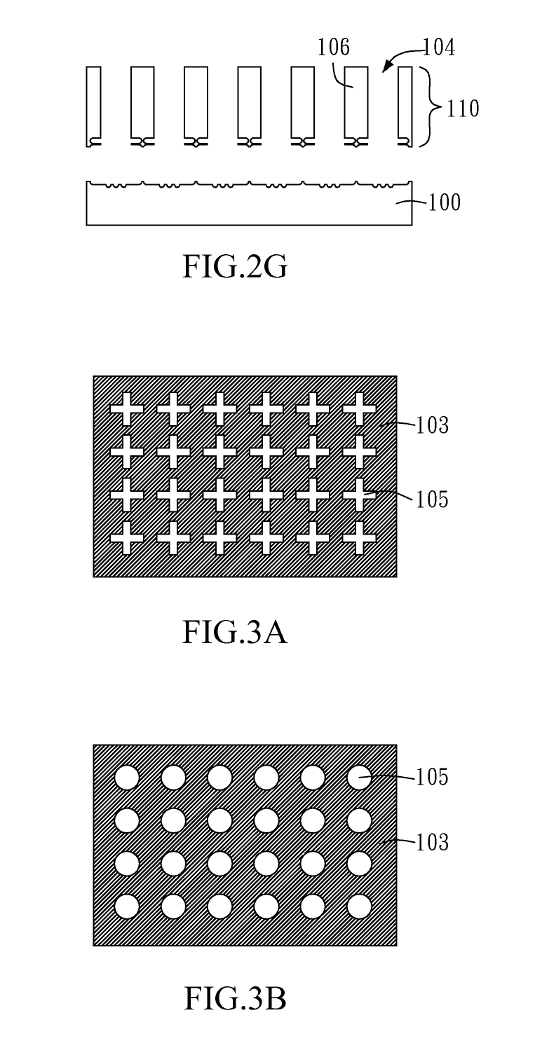

This invention also provides another method for producing a thin single crystal silicon having large surface area. FIG. 2A to FIG. 2G are a series of cross-section drawings illustrating a method for producing a thin single crystal silicon having large surface area in accordance with another embodiment of the present invention. Referring to FIG. 2A, FIG. 2B and FIG. 2C, first, the metal barrier layer 103 is formed on the substrate 100 to define the etching area 105 on the substrate 100, and the kinds of the silicon microstructure or the nanostructure produced on the substrate 100 is determined by the pattern on the metal barrier layer 103 or the pattern composed of the metal barrier layers 103. After, the metal catalyst 102 is deposited on or attached to the substrate 100, and then, the substrate 100 is dipped in the first etching solution to vertically etch the substrate 100 for forming the microstructure or the nanostructure. In the step of depositing or attaching the metal catalyst 102 on the substrate 100 shown in FIG. 2B, the metal catalyst 102 deposited on or attached to the substrate 100 directly, and the metal barrier layer determines what kind of the silicon microstructure or the nanostructure is produced. The steps shown in FIG. 2A to FIG. 2C are the same with the steps shown in FIG. 1A to FIG. 1C, and the process conditions of the steps shown in FIG. 2A to FIG. 2C are the same with the process conditions of the steps shown in FIG. 1A to FIG. 1C. Therefore they are not mentioned herein because they are described in detail.

And then, referring to FIG. 2D, the substrate 100 on which the microstructure or the nanostructure has been produced is dipped in a third etching solution in a short period of several seconds to several hours, for example 5-60 seconds (but not limited to this and can be changed and modified according to the requirements of the production process). Therefore, the metal catalyst 102, which is distributed on the bottoms of the etched holes 104 only, is distributed on and attached to the sidewalls of the etched holes (or the sidewalls of the microstructure or the nanostructure). The third etching solution is composed of a chemical solution capable of etching oxide and a chemical solution capable of oxidizing silicon, for example an aqueous solution of hydrofluoric acid (HF)/hydrogen peroxide (H₂O₂) or a mixed aqueous solution capable of oxidizing silicon and etching silicon oxide simultaneously. The third etching solution must further comprise an ingredient capable of oxidizing metal to be metal ion, for example hydrogen peroxide (H₂O₂) is also a metal oxidizing agent. The ingredient capable of oxidizing metal to be metal ion need to be increased in third etching solution for increasing metal ions produced by oxidizing the metal, for example the molar ratio of hydrogen peroxide (H₂O₂) in the aqueous solution of hydrofluoric acid (HF)/hydrogen peroxide (H₂O₂) is increased and the molar ratio of hydrofluoric acid (HF)/hydrogen peroxide (H₂O₂) is smaller than 35/1. However, this is not a limit for the third etching solution. The molar ratio of hydrofluoric acid (HF)/hydrogen peroxide (H₂O₂) in the third etching solution can be changed or modified according to requirements and concerns of production process. The temperature of the third etching solution is in the range of 10° C.-100° C.

In this step, both of the molar ratios of ingredient capable of oxidizing metal to be metal ion (for example the hydrogen peroxide (H₂O₂) in the aqueous solution of hydrofluoric acid (HF)/hydrogen peroxide (H₂O₂)) and the chemical solution capable of oxidizing silicon in third etching solution are increased because the molar ratio of the chemical solution capable of etching oxide and the chemical solution capable of oxidizing silicon (for example an aqueous solution of hydrofluoric acid (HF)/hydrogen peroxide (H₂O₂)) is reduced. Therefore, oxidizing rate of silicon (or the silicon substrate) becomes faster, and the etching rate of silicon oxide cannot fit in with the oxidizing rate of silicon so the oxidation-reduction reaction of the silicon surface becomes slower. As a result, when the substrate 100 is dipped in the third etching solution in a short time, the hydrogen peroxide (H₂O₂) oxidizes the metal catalyst 102 to form a lot of metal ions and the metal ions are distributed on the sidewalls of the etched holes 104 (or the sidewalls of the microstructure or the nanostructure), and then, the metal ions distributed on the sidewalls of the etched holes 104 are reduced to be the metal catalyst 102b and the metal is adhered on or attached to the sidewalls of the etched holes 104. Therefore, only little metal catalysts 102a still are distributed on the bottoms of the etched holes 104. Referring to actual experiment result, FIG. 5C is a SEM image in cross-section view of the sidewalls of the microstructure (or nanostructure) with metal particles attached or distributed thereon.

After, referring to FIG. 2E, the substrate 100 is dipped in a second etching solution to perform a lateral etching. As a large number of the metal catalysts 102b have been distributed on the sidewalls of the etched holes 104 in previous step, in this step, the second etching solution etches the sidewalls of the etched holes 104 immediately to create the laterally etching 108 through catalyzing of the metal catalysts 102b on the sidewalls of the etched holes 104 when the substrate 100 starts to be dipped into the second etching solution. Therefore, unlike the step shown in FIG. 1D performs the laterally etching 108 to etch the sidewalls of the etched holes 104 (or the substrate 100) after the substrate 100 has been dipped in the second etching solution for a while, the step shown in FIG. 1D performs the laterally etching 108 to etch the sidewalls of the etched holes 104 (or the substrate 100) immediately when the substrate 100 starts to be dipped into the second etching solution. This method provides a lateral etching having good directional property to the sidewalls of the etched holes 104 (or the substrate 100), and the lateral etching has the etching direction which is almost perpendicular to the sidewalls of the etched holes 104. Although there are still the metal catalyst 102a on the bottoms of the etched holes 104 and the second etching solution still etches the bottoms of the etched holes 105 through catalyzing of the metal catalyst 102a, but comparing with the step shown in FIG. 1C, this step obviously etches the sidewalls of the etched holes 104 (or the substrate 100) more. This means that this step obviously performs more lateral etching than vertical etching in this step. FIG. 5D is a SEM image in cross-section view of the bottom of the microstructure (or nanostructure) with obvious lateral etching.

In this step, the second etching solution is composed of a chemical solution capable of etching oxide and a chemical solution capable of oxidizing silicon, for example an aqueous solution of hydrofluoric acid (HF)/hydrogen peroxide (H₂O₂) or a mixed aqueous solution capable of oxidizing silicon and etching silicon oxide simultaneously. The molar ratio of the chemical solution capable of etching oxide/the chemical solution capable of oxidizing silicon in the second etching solution, for example the molar ratio of hydrofluoric acid (HF)/hydrogen peroxide (H₂O₂) is greater than 35/1, but not limited to this. The molar ratio of the chemical solution capable of etching oxide/the chemical solution capable of oxidizing silicon in the second etching solution, for example the molar ratio of hydrofluoric acid (HF)/hydrogen peroxide (H₂O₂), can be changed or modified according to requirements and concerns of production process. The molar ratio of the chemical solution capable of etching oxide/the chemical solution capable of oxidizing silicon in the second etching solution, for example the molar ratio of hydrofluoric acid (HF)/hydrogen peroxide (H₂O₂), can be equal to, smaller or greater than the molar ratio of the chemical solution capable of etching oxide/the chemical solution capable of oxidizing silicon in the first etching solution. The temperature of the second etching solution is in the range of 10° C.-100° C.

And then, referring to FIG. 2F, after the sidewalls of the etched holes 104 are laterally etched for a while, for example several minutes to several hours, it is determined according to the requirements of production process and products, the bottoms of the etched holes 104 are close to each other or the bottoms of the etched holes 104 are connected with each other by the laterally etching 108. Therefore, the silicon microstructure or the silicon nanostructure on the substrate 100 becomes a silicon microstructure thin film or a silicon nanostructure thin film 110 through the laterally etching 108, and the connections between the substrate 100 and the bottom of the silicon microstructure thin film or the silicon nanostructure thin film 110 are weakened or completely removed by the laterally etching 108. Referring to FIG. 2G, after the lateral etching, the silicon microstructure thin film or the silicon nanostructure thin film 110 is lifted off and transferred from the substrate 100. The steps of lifting off and transferring the silicon microstructure thin film or the silicon nanostructure thin film 110 shown in FIG. 2G are the same with the steps shown in FIG. 1F, and these steps are described in detail before. Therefore, they are not mentioned herein again.

Finally, after the silicon microstructure thin film or the silicon nanostructure thin film 110 is lifted off or transferred from the substrate 100, the surface of the substrate 100 is processed to planarize the surface by metal assisted etching, chemical polishing, mechanical polishing, or other methods capable of planarizing the surface of the substrate 100. By this step, the substrate 100 can be recycled for producing another silicon microstructure or another silicon nanostructure thereon. Therefore, the steps of depositing metal catalysts on the silicon wafer (or substrate), vertically etching the substrate, distribution and adhesion of the metal catalysts, laterally etching the substrate, lifting off and transferring the silicon microstructure (thin film) or the silicon nanostructure (thin film), and treatment of the surface of substrate shown in FIG. 2A to FIG. 2G are repeated to produce desired silicon microstructures or silicon nanostructures repeatedly, and the substrate is recycled repeatedly until the thickness, the hardness or other qualities of the substrate 100 cannot meet the requirements and conditions of the production process any more.

However, no matter which method for producing a thin single crystal silicon having large surface area disclosed in above-mentioned embodiments, both of them can form an oxide layer on the surface of the thin single crystal silicon by thermal oxidation or grow a silicon oxide or silicon nitride on the surface of the thin single crystal silicon by chemical vapor deposition (CVD). Therefore, surface bonding is created on the surface of the silicon microstructure thin film or the silicon nanostructure thin film (the thin single crystal silicon) for protecting the surface thereof and for reducing number of surface energy levels and recombination probability of surface carriers.

Therefore, according to disclosures of above-mentioned embodiments, this invention provides a simple and cheap method for producing a thin single crystal silicon having large surface area. In this method, the metal assisted etching having the advantages of simple production process, low process temperature (10° C.-100° C.), and no requirement of expensive device is used instead of vapor-liquid-solid (VLS), chemical vapor deposition, thermal evaporation, or solution method, which has the disadvantages of high vacuum, high process temperature, high pressure, and requirement of expensive device, to provide a low temperature, simple and low cost process for producing the silicon microstructure thin film or the silicon nanostructure thin film (the thin single crystal silicon). Furthermore, in this method, the etching solutions having different molar ratio of the ingredients, the chemical solutions having different molar ratio of a chemical solution capable of etching oxide and a chemical solution capable of oxidizing silicon, are used to transform the vertical etching for producing the silicon microstructure thin film or the silicon nanostructure thin film (the thin single crystal silicon) into the lateral etching, or they are used to help to lift off and transfer the silicon microstructure thin film or the silicon nanostructure thin film (the thin single crystal silicon) form the substrate or are used to directly lift off and transfer the silicon microstructure thin film or the silicon nanostructure thin film (the thin single crystal silicon) form the substrate. Therefore, the substrate is recycled and used to produce the thin single crystal silicon repeatedly. Therefore, this invention uses the metal assisted etching having the advantages of simple production process, low process temperature (10° C.-100° C.), and low cost to produce the thin single crystal silicon. By this method, the substrate is not utilized to produce the thin single crystal silicon just one time but it can be utilized to produce the thin single crystal silicon until the thickness, the hardness or other qualities of the substrate cannot meet the requirements and conditions of the production process any more. Therefore, the production process of the silicon microstructure (or the silicon nanostructure) is simplified and the cost of the producing process can be reduced by this method.

What is claimed is:

1. A method for producing a thin single crystal silicon having large surface area, comprising:
(1) providing a substrate made of a single material;
(2) forming a designed and patterned metal barrier layer on said substrate to define an etching area on said substrate;
(3) depositing or attaching a metal catalyst on said substrate;
(4) dipping said substrate into a first etching solution to vertically etching said substrate to form a microstructure or a nanostructure;
(5) dipping said substrate into a second etching solution to laterally etching bottom of said microstructure or said nanostructure to lift off said microstructure or said nanostructure from said substrate;
(6) transferring said microstructure or said nanostructure from said substrate; and
(7) processing a surface of said substrate for forming another microstructure or nanostructure on said substrate.

2. The method of claim 1, wherein after step (7), step (1)-step (7) are repeated to form a microstructure or a nanostructure on said substrate repeatedly.

3. The method of claim 1, wherein said substrate is a silicon (Si) substrate or silicon (Si) wafer.

4. The method of claim 1, wherein said metal catalyst is selected from a group consisting of gold (Au), silver (Ag), platinum (Pt), copper (Cu), iron (Fe), manganese (Mn), and cobalt (Co) which are metals capable of being used as redox mediators.

5. The method of claim 1, wherein said step (3) is performed by electroless metal deposition (EMD), sputter, e-beam evaporation, or thermal evaporation to deposit or attach said metal catalyst on said substrate.

6. The method of claim 5, wherein in said step (3), a solution used in said electroless metal deposition (EMD) is selected from a group consisting of an aqueous solution of hydrofluoric acid (HF)/potassiumchloroaurate (KAuCl₄), an aqueous solution of hydrofluoric acid (HF)/silver nitride (AgNO₃), an aqueous solution of hydrofluoric acid (HF)/potassium hexachloroplatinate (K₂PtCl₄), an aqueous solution of hydrofluoric acid (HF)/copper nitride (Cu(NO₃)₂), an aqueous solution of hydrofluoric acid (HF)/ferric nitride (Fe(NO₃)₃), an aqueous solution of hydrofluoric acid (HF)/manganous nitride (Mn(NO₃)₃), and an aqueous solution of hydrofluoric acid (HF)/cobaltous nitride (Co(NO₃)₃).

7. The method of claim 1, wherein said metal barrier layer is a photoresist, organic polymer, silicon oxide (SiₓO_{y}), or silicon nitride (SiₓN_{y}).

8. The method of claim 1, wherein said step (2) is performed by photo lithography, electron-beam lithography, microsphere array or nanosphere array, or imprint lithography to define said etching area on said substrate.

9. The method of claim 1, wherein said first etching solution is an aqueous solution of hydrofluoric acid (HF)/hydrogen peroxide (H₂O₂).

10. The method of claim 9, wherein the temperature of said first etching solution is at 10° C.-100° C.

11. The method of claim 9, wherein said second etching solution is an aqueous solution of hydrofluoric acid (HF)/hydrogen peroxide (H₂O₂).

12. The method of claim 11, wherein the temperature of said second etching solution is at 10° C.-100° C.

13. The method of claim 11, wherein the molar ratio of hydrofluoric acid (HF)/hydrogen peroxide (H₂O₂) of said second etching solution is lower than the molar ratio of hydrofluoric acid (HF)/hydrogen peroxide (H₂O₂) of said first etching solution.

14. The method of claim 1, wherein in step (5), a microstructure thin film or a nanostructure thin film is formed after said microstructure or said nanostructure is laterally etched.

15. The method of claim 14, wherein said microstructure thin film or said nanostructure thin film has a thickness of 50 nm-1000 nm.

16. The method of claim 14, wherein said microstructure thin film or said nanostructure thin film is a microwire thin film or nanowire thin film, a microhole thin film or nanohole thin film, a microrod thin film or nanorod thin film, a bar-like microstructure thin film or bar-like nanostructure thin film, or a network-like microstructure thin film or network-like nanostructure thin film.

17. The method of claim 14, wherein said step (6) is performed by scraping said microstructure thin film or said nanostructure thin film from said substrate to form a powder structure or a sheet-like structure.

18. The method of claim 17, wherein the area of said sheet-like structure is 50 nm²-10 μm².

19. The method of claim 1, wherein said step (6) is performed by transfer printing, sticking, or material stress to lift off said microstructure or said nanostructure from said substrate and transfer said microstructure or said nanostructure to a carrier substrate.

20. The method of claim 19, wherein said carrier substrate comprises silicon, III-V semiconductor, glass, transparent conductive glass, plastic substrate, or metal plate or foil.

21. The method of claim 19, wherein in said step (6), there is an adhesive material between said microstructure or said nanostructure and said carrier substrate for attaching said microstructure or said nanostructure to said carrier substrate.

22. The method of claim 21, wherein said adhesive material is a polymer, conductive organic material, metal adhesive, electron and hole transport material, or photon transport material.

23. The method of claim 1, wherein said step (7) is performed by metal assisted etching, chemical polishing, mechanical polishing to planarize the surface of said substrate for recycling said substrate to form another microstructure or nanostructure on said substrate again.

24. The method of claim 1, wherein further comprising a step of dipping said substrate on which said microstructure or said nanostructure was formed in a third etching solution to distribute said metal catalyst on sidewalls of said microstructure or said nanostructure and to attach said metal catalyst thereon.

25. The method of claim 24, wherein said step of dipping said substrate in a third etching solution is performed after step (4) but before step (5).

26. The method of claim 24, wherein said third etching solution is an aqueous solution of hydrofluoric acid (HF)/hydrogen peroxide (H₂O₂).

27. The method of claim 26, wherein the temperature of said third etching solution is at 10° C.-100° C.

28. The method of claim 26, wherein the molar ratio of hydrofluoric acid (HF)/hydrogen peroxide (H₂O₂) of said third etching solution is lower than the molar ratio of hydrofluoric acid (HF)/hydrogen peroxide (H₂O₂) of said first etching solution.

29. The method of claim 26, wherein the molar ratio of hydrofluoric acid (HF)/hydrogen peroxide (H₂O₂) of said second etching solution used in step (5) is equal to the molar ratio of hydrofluoric acid (HF)/hydrogen peroxide (H₂O₂) of said first etching solution, or lower or greater than the molar ratio of hydrofluoric acid (HF)/hydrogen peroxide (H₂O₂) of said first etching solution.

30. The method of claim 1, wherein further comprising a surface bonding to be created on said thin single crystal silicon for protecting the surface of said thin single crystal silicon and for reducing number of surface energy levels and probability of recombination of surface carriers.

31. The method of claim 31, wherein said surface bonding is created by thermal oxidation to form an oxide layer on the surface of said thin single crystal silicon or by chemical vapor deposition (CVD) to grow a silicon oxide or silicon nitride on surface of said thin single crystal silicon.
